(19) United States
(12) Patent Application Publication
(10) Pub. No.: US 2019/0207719 A1
(43) Pub. Date: Jul. 4, 2019

(54) METHOD OF HYBRID AUTOMATIC REPEAT REQUEST IMPLEMENTATION FOR DATA TRANSMISSION WITH MULTI-LEVEL CODING

(71) Applicant: LIMITED LIABILITY COMPANY "RADIO GIGABIT", Nizhny Novgorod (RU)

(72) Inventors: Andrey Arkad'evich SHEVCHENKO, Nizhniy Novgorod (RU); Aleksey Ur'evich TRUSHANIN, Nizhniy Novgorod (RU); Vyacheslav Ur'evich SHUMILOV, Nizhniy Novgorod (RU); Maksim Vital'evich MAKHLYSHEV, Nizhniy Novgorod (RU); Roman Olegovich MASLENNIKOV, Nizhniy Novgorod (RU)

(21) Appl. No.: 16/226,690

(22) Filed: Dec. 20, 2018

(30) Foreign Application Priority Data
Dec. 29, 2017 (RU) 2017146997

(51) Int. Cl. H04L 1/18; H04L 1/00; H04L 5/00; H03M 13/09; H03M 13/11

(52) U.S. Cl. CPC H04L 1/1819; H04L 1/0061; H03M 13/1102; H03M 13/096; H04L 5/0055

(57) ABSTRACT

A method of Hybrid Automatic Repeat Request implementation which efficiently combines received signals from multiple H-ARQ block transmission attempts encoded by the Multi-Level Coding approach with an uncoded subset of information bits. The method is to provide full error correction gains of the H-ARQ scheme and decoder computational complexity reduction due to transmission of uncoded bits and does not cause significant demodulator and signal processing complexity growths. The advantages are achieved via calculation of likelihood ratio metrics and their combining between at least two different data block transmission attempts for both encoded and uncoded bits of a data block. Besides, calculation of likelihood ratio metrics for uncoded bits is performed considering results of decoding of the encoded bits. Receiver decisions on values of uncoded bits are made based on values of combined likelihood ratio metrics for uncoded bits.

### FIELD OF THE TECHNOLOGY

The present invention is generally related to the field of electrical communication and more specifically to apparatus and methods that can reduce a Bit Error Rate (BER) of signal transmission in broadband telecommunication systems.

### BACKGROUND

Modern wireless communication systems use Forward Error Correction (FEC) to protect a transmitted signal against possible errors occurred in a communication channel. The main principle of FEC is introducing redundancy into a transmitted information data sequence to form an encoded data sequence. The encoded sequence is modulated and transmitted through the communication channel. The received signal is demodulated and decoded at the receiver allowing to restore the information sequence with correction of all errors or a part of errors in the received encoded sequence. Computational complexity of the decoder determining the required computational resources of the receiver for its implementation is of great importance for proper code selection especially in communication systems with high throughput (1 Gbit/s and more). An example of widely spread high-performance codes with relatively small computational complexity is the Low-Density Parity Check (LDPC) codes. At the same time, despite using codes with low computational complexity and optimal decoder architectures, the computational complexity of the decoder grows significantly with increasing orders of digital modulation and the throughput.

The Multi-Level Coding (MLC) scheme is a special case of forward error correction and digital data modulation. Basic principles of MLC were disclosed in the research paper of H. Imai (Yokohama National University, Japan) and S. Hirakawa (University of Tokyo, Japan) “A new multilevel coding method using error-correcting codes”, IEEE Transactions on Information Theory, v. It-23, no. 3, 1977, prototype. In this paper the authors propose an efficient and simple FEC method for signals with multiple (more than two) states. There it is proposed to split multiple signal states into subsets encoded by binary signals with different levels of error protection. The binary signals of different levels are independently encoded by binary FEC codes. For more protected bits a code with a higher code rate, i.e. a higher ratio of lengths of the information sequence and the total encoded sequence, is proposed. For less protected bits a code with a lower code rate is proposed. The authors have shown that this approach allows moving from binary to multilevel signals (with the number of states more than two) using the Ungerboek modulation and binary FEC codes without losing the overall capacity.

The paper shows that to keep the error correction efficiency the received signal must be decoded using the Multi-Stage Decoding (MSD) method as shown in FIG. 1. At the first stage the received signal samples are demodulated by the interpreter I1, then the least protected bits are decoded by the binary decoder D1. The results of D1 are sent to the interpreter of signal samples of the second stage I2. Demodulation and decoding by I2 and D2 are performed in awareness of the output of D1, and so forth. Therefore, subsequent stages of demodulation and decoding of more protected bits of a signal sample use a priori information about encoded bits from previous stages.

Interest in multi-level coding is currently associated with the use of high-order modulations in wideband communication systems with high throughputs. A practically important application of the MLC technology consists in transmission of more protected bits without coding and transmission of less protected bits coded usually. This allows reducing the number of encoded and decoded bits per symbol, and therefore limiting the growth of the computational complexity of the decoder with increasing the modulation order. This application of MLC is noted, for example, in the paper of U. Wachsmann, et al., “Multilevel codes: theoretical concepts and practical design rules”, IEEE Transactions on Information Theory, v. 45, no. 5, 1999.

The Automatic Repeat Request (ARQ) technology is an independent mechanism of error protection which requires presence of a feedback control channel. Data transmission in this approach is performed by blocks with redundant information (e.g. the Cyclic Redundancy Check (CRC) checksum) added to each block to detect errors. According to error check results the receiver generates and sends over the feedback channel an acknowledgment (ACK) or a request for the block retransmission (negative acknowledgement—NACK). Retransmissions are performed until either the block is received without errors or the maximum number of retransmissions or the maximum block waiting time is reached which is determined by system characteristics. One of the major drawbacks of the ARQ scheme is low efficiency of time resource utilization because of decoding of each transmission attempt independently of earlier attempts.

The principle of Hybrid automatic repeat request (H-ARQ) method is in FEC encoding of initially sent data with a relatively low redundancy (high coding rate), checking for errors at the receiver and generating ACK or NACK messages similarly to the ARQ scheme. In the case of unsuccessful decoding of the original data block the original block information and the received retransmission information are combined to effectively increase the redundancy (reduce the coding rate). The most computationally simple way of information combining applicable to systems with coding all transmitted bits is mathematical addition of the Logarithmic Likelihood Ratio metrics (LLR). These metrics are calculated by the demodulator and used for data decoding. In the H-ARQ scheme if an error is detected after verifying the checksum of the decoded block, the calculated LLR values are stored at the receiver and added to the LLR values calculated for the retransmitted data block. The combined LLR metric after each retransmission is used for a new decoding attempt.

To combine gains of the H-ARQ scheme in error protection and reduction of computational complexity for high-order modulations it is practically reasonable to apply the schemes of H-ARQ and MLC without encoding a part of the information bits together. In that case the LLR calculation is necessary only for the encoded subset of bits of the block for further usage by the decoder. For the uncoded subset of bits the receiver determines the transmitted values of bits by a threshold decision depending on the value of a received signal sample, where the threshold is defined by the decoded bit values from the encoded subset. Considering the described feature of the multilevel coding scheme without coding of a part of information bits the LLR summation of several block transmission attempts for H-ARQ is possible only for the encoded subset of the code word bits. In that case, the values of uncoded bits can be determined by a threshold decision using only a single block transmission attempt. The described implementation significantly reduces the overall efficiency of H-ARQ due to limiting the total probability of bit errors in a block by a probability of a bit error in uncoded bits of a single transmission attempt. A solution to this problem may be in increasing the number of encoded bits in signal samples which in turn leads to increasing the decoder computational complexity and reducing the MLC efficiency.

An alternative way of combining the received information of multiple transmission attempts in the H-ARQ scheme can be realized by performing a preliminary averaging of received symbols between attempts with weights depending on the signal-to-noise ratios (SNR) for different transmission attempts. In systems with encoding of all bits this method is mathematically equivalent to LLR summation. However, this method is not used in practice because of a need for additional calculation of the averaging weights depending on SNR values after receiving each next transmission attempt and calculating the averaged symbols for each transmission attempt. Such a need additionally increases the computational complexity of receiver signal processing.

In MLC systems with uncoded transmission of a part of the information bits this approach however can be used to fully keep the H-ARQ efficiency. But, on the other hand, the need for additional calculations at the symbol level increases the computational complexity of the receiver. An additional increase of computational complexity at the symbol level in the demodulator and signal preprocessing schemes eliminates the decoder computational complexity reduction due to the MLC with uncoded part of information bits. In some cases, this leads to inexpediency of joint implementation of the H-ARQ and MLC and to impossibility of getting H-ARQ gains in cases where MLC application is required due to receiver computational resource limitation.

Thus, there is a need for a method for efficient combining of the received signals from multiple H-ARQ block transmission attempts encoded using MLC with an uncoded subset of information bits. The method is to provide full gains of error correction of the H-ARQ scheme and decoder computational complexity reduction due to transmission of uncoded bits but is not to cause a significant demodulator and symbol-level signal processing complexity growths.

### SUMMARY

An object of the invention is to propose a method of Hybrid Automatic Retransmission Request (H-ARQ) implementation for data transmission with Multi-Level Coding (MLC) with an uncoded subset of information bits.

A technical result of the claimed invention is expressed in decreasing computational complexity of a demodulator and received symbol processing schemes and increasing error protection performance due to joint implementation of H-ARQ and MLC with an uncoded subset of information bits.

The technical result is achieved by calculation of likelihood ratio metrics and their combining between at least two different data block transmission attempts for both the encoded and uncoded bits of a data block. Besides calculation of the likelihood ratio metrics for the uncoded bits is performed considering the results of decoding of the encoded bits. Decisions of a receiver on values of the uncoded bits are made based on values of combined likelihood ratio metrics for the uncoded bits.

Implementation of H-ARQ in communication systems with MLC includes (a) performing the first transmission of a data block with a part of bits encoded with a FEC code and with the other part of bits uncoded; (b) receiving the first transmission of a data block, performing demodulation and decoding of the encoded part of bits of the received data block; (c) checking the received data block for errors and sending a retransmission request to the transmitter if errors are detected; (d) performing the second transmission of the same data block upon receipt of a retransmission request; and (e) receiving the second transmission of the data block, performing demodulation and decoding of the encoded part of bits of the received data block accompanied by combining the information obtained after reception of the first and the second transmissions of the data block.

The claimed method differs from other possible methods by comprising the following successive steps in reception of the first transmission of a data block: (b.1) demodulation of signal samples of the first transmission and calculation of likelihood ratio metrics for the encoded bits; (b.2) decoding of the encoded bits using the calculated metrics; (b.3) demodulation of signal samples of the first transmission and calculation of likelihood ratio metrics for the uncoded bits using the results of the decoding of the encoded bits; and (b.4) making decisions on values of the uncoded bits using the calculated likelihood ratio metrics for the uncoded bits. Moreover the method comprises performing the following successive steps in combining the information obtained after reception of the first and the second transmissions of the data block: (d.1) demodulating signal samples of the second transmission and calculating likelihood ratio metrics for the encoded bits; (d.2) combining the likelihood ratio metrics calculated for the encoded bits of the first and the second transmissions of the data block; (d.3) decoding of the encoded bits using the combined likelihood ratio metrics for the encoded bits; (d.4) demodulation of signal samples of the second transmission and calculation of likelihood ratio metrics for the uncoded bits using the results of the decoding of the encoded bits; (d.5) combination of the likelihood ratio metrics calculated for the uncoded bits of the first and the second transmissions of the data block; and (d.6) making decisions on values of the uncoded bits using the combined likelihood ratio metrics for the uncoded bits.

In one embodiment, the first and the second transmissions of a data block are two consecutive transmissions in a sequence of two or more transmissions of the same data block.

In another embodiment, likelihood ratio metrics for encoded or uncoded bits are calculated in the logarithmic scale. In more specific embodiments a piecewise linear approximation is used to calculate likelihood ratio metrics in the logarithmic scale as a function of a received signal sample. In one of the more specific embodiments combination of likelihood ratio metrics in the logarithmic scale consists in their algebraic addition. In another specific embodiment making decisions on values of uncoded bits consists in determining of a sign of a likelihood ratio metric in the logarithmic scale.

In another embodiment, encoded and uncoded bits are modulated using the Ungerboeck modulation.

In one embodiment, a block code is used to encode bits and the encoded bits of a data block are divided into equal groups and each of these groups is encoded and decoded independently.

In one more embodiment, a Low-Density Parity Check (LDPC) code is used to encode bits.

### BRIEF DESCRIPTION OF THE DRAWINGS

Further features and advantages of the present invention will become apparent from the following description of preferred embodiments with reference to accompanying drawings.

FIG. 1—a general scheme of multi-level decoding of a received signal (prior art).

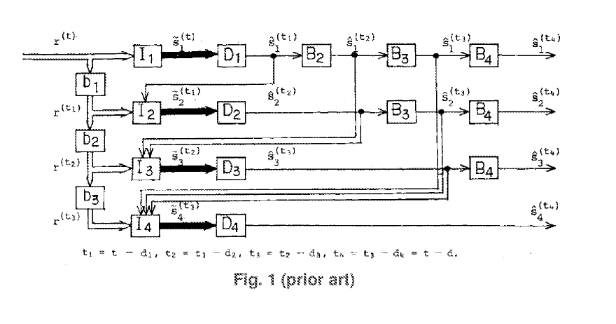

FIG. 2—a general scheme of data transmission with H-ARQ.

FIG. 3—a transmitter functional diagram.

FIG. 4—a receiver functional diagram.

There are following details denoted in the figures:

101—a source of information, 102—a data block generation module, 103—a transmitter, 104—a data transmission channel, 105—a receiver, 106—a data block error checking module, 107—a feedback control channel, 108—a recipient of information, 201—a transmitted data block, 202—a module of data separation into the encoded and uncoded parts, 203—an encoder, 204—a modulator of encoded bits, 205—a modulator of uncoded bits, 206—a resulting modulated signal, 301—a received signal, 302—a demodulator of encoded bits, 303—a module for combining LLR values of encoded bits from multiple transmissions, 304—a decoder, 305—a read and write controller for the combined LLR values of encoded bits, 306—memory, 307—a demodulator of uncoded bits, 308—a module for combining LLR values of uncoded bits from multiple transmissions, 309—a threshold device, 310—a read and write controller for the combined LLR values of uncoded bits, 311—memory, 312—a data combining module, 313—a resulting bit sequence of a data block.

### DETAILED DESCRIPTION OF THE INVENTION

A description of embodiments of the claimed method of Hybrid Automatic Retransmission Request (H-ARQ) implementation for data transmission with Multi-Level Coding (MLC) with an uncoded subset of information bits is provided below. The method includes: (a) performing the first transmission of a data block with a part of bits encoded with a forward error correction (FEC) code and with the other part of bits uncoded; (b) receiving the first transmission of a data block, performing demodulation and decoding of the encoded part of bits of the received data block; (c) checking the received data block for errors and sending a retransmission request to the transmitter if errors are detected; (d) performing the second transmission of the same data block upon receipt of a retransmission request; and (e) receiving the second transmission of the data block, performing demodulation and decoding of the encoded part of bits of the received data block accompanied by combining the information obtained after reception of the first and the second transmissions of the data block.

The transmitted data block b={b0, b1, . . . bN-1} with the size of N bits is divided into two bit sequences bc and u representing the encoded and uncoded subsets of the block bits. A size of the encoded sequence is Nc=Nsymb·mc·R, a size of the uncoded sequence is Nu=Nsymb·mu provided that N=Nc+Nu, where Nsymb is the number of signal samples (symbols), mc and mu are the numbers of encoded and uncoded bits of a single signal sample respectively, R is a code rate for the encoded bits. The bit sequence bc is converted by a FEC code with a rate of R into an encoded bit sequence c={c0, c1, . . . cNcod-1} with the length of Ncod=Nsymb·mc. The encoded sequence c is divided into Nsymb blocks c(k), k=0, . . . , Nsymb-1, each of them has mc bits provided that each block is used to modulate a separate signal sample. The uncoded sequence u is divided into Nsymb blocks u(k), k=0, . . . , Nsymb-1, each of them has mu bits provided that each block is used to modulate a separate signal sample.

Modulation of each signal sample s(k), k=0, . . . , Nsymb-1 is performed as follows. A block of the encoded sequence c(k) is mapped onto a signal sample sg(k) using the Gray code. A block of the uncoded sequence u(k) is mapped onto an offset signal su(k) using the Ungerboeck code. A resulting signal sample s(k) is calculated by adding the offset su(k) to the signal sample sg(k):

s(k)=s_{g}(k)+sᵤ(k).

After modulation of all Nsymb signal samples of the block the signal s={s(0), s(1), . . . , s(Nsymb-1)} is transmitted through a communication channel. The transmitted signal s is the same for both the first and the second transmissions of the data block.

Demodulation and decoding of the received signal r={r(0), r(1), . . . r(Nsymb-1)} corresponding to the transmitted signal s for both the first and the second transmissions include demodulation of signal samples and calculation of likelihood ratio metrics for the encoded bits; decoding the encoded bits using the calculated metrics, demodulation of signal samples and calculation of likelihood ratio metrics for the uncoded bits using the results of the decoding of the encoded bits; and making decisions on values of the uncoded bits using the calculated likelihood ratio metrics for the uncoded bits.

Demodulation of the encoded bits c(k) is independently performed for each received signal sample r(k), k=0, . . . , Nsymb-1. In a specific embodiment, a likelihood ratio metric in the logarithmic scale (LLR) is calculated for each bit c(k)i from c(k), i=0, . . . , mc-1:

$$LLR ( {c ( k )}_{i} ) = log \frac{{\sum }_{α ∈ {S}_{i}^{( 1 )}} p ( r ( k ) \vert s ( k ) = α )}{{\sum }_{α ∈ {S}_{i}^{( 0 )}} p ( r ( k ) \vert s ( k ) = α )} ,$$

where Si(1) and Si(0) denote subsets of a set of all possible values of a transmitted signal sample s with the i-th encoded bit defined as ci=1 and ci=0 respectively, p( ) denotes a conditional (a posteriori) probability density function.

In an embodiment, a piecewise linear approximation is applied to calculate likelihood ratio metrics in the logarithmic scale as a function of a received signal sample which can be expressed as:

$$LLR ( {c ( k )}_{i} ) = \frac{1}{2 {σ}^{2}} ( {min}_{α ∈ {S}_{i}^{( 0 )}} {\vert r ( k ) - α \vert}^{2} - {min}_{a ∈ {S}_{i}^{( 1 )}} {\vert r ( k ) - α \vert}^{2} ) ,$$

where σ2 additionally denotes the noise variance in a received signal sample r(k).

The set of Nsymb·mc calculated metrics for all bits of the encoded sequence c is used for decoding. Decisions of the receiver on values of the bits in the be and c sequences that are denoted by bc(est) and c(est) respectively are expressed in the results of the decoding.

Demodulation of the uncoded bits u(k) is also independently performed for each received signal sample r(k), k=0, . . . , Nsymb-1. In a specific embodiment, an LLR is calculated for each bit u(k)i from u(k), i=0, . . . , mu-1:

$$LLR ( {u ( k )}_{j} ) = log \frac{{\sum }_{α ∈ {S}_{j}^{( 1 )} ( {c ( k )}^{( est )} )} p ( r ( k ) \vert s ( k ) = α )}{{\sum }_{α ∈ {S}_{j}^{( 0 )} ( {c ( k )}^{( est )} )} p ( r ( k ) \vert s ( k ) = α )} ,$$

where Sj(1)(c(k)(est)) and Sj(0)(c(k)(est)) denote subsets of a set of all possible values of a transmitted signal sample s with the j-th uncoded bit defined as uj=1 and uj=0 respectively and mc values of the encoded bits are equal to the values of bits in c(k)(est) for the current k-th signal sample.

In one embodiment, a piecewise linear approximation is applied to calculate likelihood ratio metric in the logarithmic scale as a function of a received signal sample which can be expressed as:

$$LLR ( {u ( k )}_{j} ) = \frac{1}{2 {σ}^{2}} ( {min}_{α ∈ {S}_{j}^{( 0 )} ( {c ( k )}^{( est )} )} {\vert r ( k ) - α \vert}^{2} - {min}_{a ∈ {S}_{j}^{( 1 )} ( {c ( k )}^{( est )} )} {\vert r ( k ) - α \vert}^{2} ) .$$

In another embodiment, making decisions on values of the uncoded bits consists in determining a sign of an LLR for the uncoded bits. For the above notations the positive sign of an LLR(u(k)j) corresponds to the bit value of 1 and the negative sign corresponds to the bit value of 0.

The sequence of decisions u(est) for all the Nsymb·mu uncoded bits and the sequence of decisions bc(est) for the encoded bits are combined into a sequence of decisions for the entire data block b(est).

A combination of LLR metrics for the encoded bits LLR(c(k)i) and the uncoded bits LLR(u(k)j) calculated for the first and the second data block transmissions after the second data block transmission is performed independently for each bit via their algebraic addition. The combined metrics for the encoded bits are then used for decoding of the encoded bits and the combined metrics for the uncoded bits are then used for making decisions on values of the uncoded bits.

The first and the second transmissions of a data block in the above description are two consecutive transmissions in a sequence of two or more transmissions of the same data block.

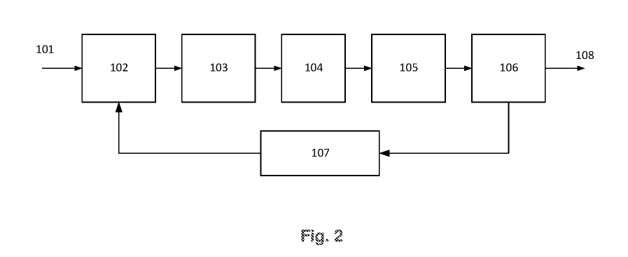

A general scheme of data transmission using MLC and H-ARQ in an embodiment is provided in FIG. 2 and includes the following steps.

A message is transmitted from a source of information (101) to a data block generation module (102) where a checksum for integrity verification is added. The generated data block is then used at a transmitter (103) to generate a signal sequence. The signal sequence is transmitted through a data transmission channel (104) to a receiver (105) performing demodulation of the sequence and data decoding. A data block error checking module (106) performs error checks in the data block using the checksum. If there are no errors, the received block is transmitted to a recipient of information (108) and an acknowledgment (ACK) is sent over a feedback control channel (107). In the case of errors, a negative acknowledgment (NACK) is sent over the feedback channel (107). Upon receiving a NACK, the transmitter (103) retransmits the same signal sequence through the data transmission channel (104) to the receiver (105). The receiver (105) performs a combination of the information of the first and the second transmissions of the data block and performs demodulation and decoding of the data again. Then, the data block error checking module (106) performs error checks in the decoded data block again and the procedure is repeated until the block is correctly received or the maximum number of retransmissions of the data block is reached.

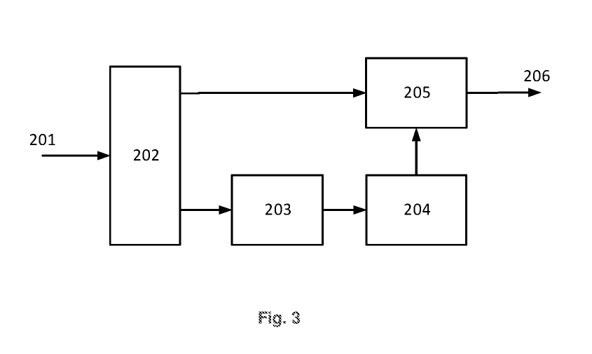

A diagram of a transmitter for an embodiment of the method is provided in FIG. 3 and includes a module of data separation into the encoded and uncoded parts (202) of a transmitted data block (201), an encoder (203), a modulator of encoded bits (204) and a modulator of uncoded bits (205) converting signal samples of the encoded bits to the resulting modulated signal (206).

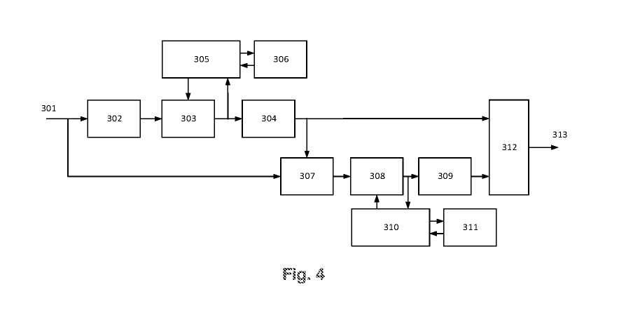

A diagram of a receiver for an embodiment of the method is provided in FIG. 4. The functional diagram includes the following components: a received signal (301) passed through a communication channel, a demodulator of encoded bits (302) calculating likelihood ratio metrics for encoded bits, a module for combining LLR values of encoded bits from multiple transmissions (303), a read and write controller for the combined LLR values of encoded bits (305) into a memory (306) of the module, a decoder (304) of a sequence of LLR metrics for encoded bits, a demodulator of uncoded bits (307) calculating likelihood ratio metrics of uncoded bits, a module for combining LLR values of uncoded bits from multiple transmissions (308), a read and write controller for the combined LLR values of uncoded bits (310) into a memory (311) of the module, a threshold device (309) making decisions on values of uncoded bits based on values of the combined LLR metrics and a data combining module (312) which restores a resulting bit sequence of a data block (313) according to the separation of bits performed by a transmitter. In this embodiment the LLR combining by a module for combining LLR values of encoded bits from multiple transmissions (303) and a module for combining LLR values of uncoded bits from multiple transmissions (308) is performed during the second and subsequent transmissions of a block. For the first transmission the corresponding metrics calculated by the demodulator are passed to the decoder (304) and the threshold device (309) and written to the memory without changes.

In an embodiment, a block code is used to encode bits and the bits of a data block to be encoded are divided into equal groups encoded and decoded by the decoder (304) independently.

In an embodiment, a Low-Density Parity Check (LDPC) code being applied in many communication systems is used to encode bits that makes the claimed method applicable to modern multi-gigabit data transmission networks.

Data processing by the receiver in the method described above does not require additional computational operations with signal samples. The information combining for uncoded bits of the first and the second transmissions of a data block is performed by operations of calculation and addition of LLR metrics for uncoded bits which have complexity not exceeding the complexity of a standard demodulator for encoded bits. In addition, in specific embodiments the same receiver computational resources can be used for calculation of LLR metrics for the encoded and uncoded bits. At the same time, gains in error correction due to H-ARQ usage and gains in the decoder computational resources due to transmission of uncoded bits are fully realized in the described method.

Therefore, the claimed invention provides reduction of receiver computational complexity for joint implementation of H-ARQ and MLC with an uncoded subset of information bits keeping all advantages of the said schemes.

The invention was disclosed above with a reference to its specific embodiments. Specialists may suggest other implementations of the invention that do not alter its essence as it is described above. Therefore, the invention should be limited only by the following claims.

1. A method of Hybrid Automatic Repeat Request implementation for data transmission with Multi-Level Coding comprising:
performing the first transmission of a data block containing N signal samples with a part of bits of the data block encoded with a Forward Error Correction code;
receiving the first transmission of a data block, performing demodulation and decoding of the encoded part of bits of the received data block;
checking the received data block for errors and sending a retransmission request to the transmitter if errors are detected;
performing the second transmission of the same data block upon receipt of a retransmission request;
receiving the second transmission of the data block, performing demodulation and decoding of the encoded part of bits of the received data block accompanied by combining the information obtained after reception of the first and the second transmissions of the data block;
wherein receiving the first transmission of a data block comprises:
demodulation of signal samples of the first transmission and calculation of likelihood ratio metrics for the encoded bits;
decoding of the encoded bits using the calculated metrics;
demodulation of signal samples of the first transmission and calculation of likelihood ratio metrics for the uncoded bits using the results of the decoding of the encoded bits;
making decisions on values of the uncoded bits using the calculated likelihood ratio metrics for the uncoded bits;
wherein combining the information obtained after reception of the first and the second transmissions of the data block comprises:
demodulation of signal samples of the second transmission and calculation of likelihood ratio metrics for the encoded bits;
combination of the likelihood ratio metrics calculated for the encoded bits of the first and the second transmissions of the data block;
decoding of the encoded bits using the combined likelihood ratio metrics for the encoded bits;
demodulation of signal samples of the second transmission and calculation of likelihood ratio metrics for the uncoded bits using the results of the decoding of the encoded bits;
combination of the likelihood ratio metrics calculated for the uncoded bits of the first and the second transmissions of the data block;
making decisions on values of the uncoded bits using the combined likelihood ratio metrics for the uncoded bits.

2. The method according to claim 1, wherein the first and the second transmissions of a data block are two consecutive transmissions in a sequence of two or more transmissions of the same data block.

3. The method according to claim 1, wherein likelihood ratio metrics for encoded or uncoded bits are calculated in the logarithmic scale.

4. The method according to claim 3, wherein a piecewise linear approximation is used to calculate likelihood ratio metrics in the logarithmic scale as a function of a received signal sample.

5. The method according to claim 3, wherein a combination of likelihood ratio metrics in the logarithmic scale consists in their algebraic addition.

6. The method according to claim 3, wherein making decisions on values of uncoded bits consists in determining a sign of a likelihood ratio metric in the logarithmic scale.

7. The method according to claim 1, wherein encoded and uncoded bits are modulated using the Ungerboeck modulation.

8. The method according to claim 1, wherein a block code is used to encode bits and encoded bits of a data block are divided into equal groups which are encoded and decoded independently.

9. The method according to claim 1, wherein a Low-Density Parity Check code is used to encode bits.
